(19) United States
(12) Patent Application Publication
(10) Pub. No.: US 2016/0068996 A1
(43) Pub. Date: Mar. 10, 2016

(54) SUSCEPTOR AND PRE-HEAT RING FOR THERMAL PROCESSING OF SUBSTRATES

(71) Applicant: Applied Materials, Inc., Santa Clara, CA (US)

(72) Inventors: Shu-Kwan LAU, Sunnyvale, CA (US); Mehmet Tugrul SAMIR, Mountain View, CA (US); Aaron MILLER, Sunnyvale, CA (US)

(21) Appl. No.: 14/826,287

(22) Filed: Aug. 14, 2015

Related U.S. Application Data
(60) Provisional application No. 62/046,451, filed on Sep. 5, 2014.

(51) Int. Cl. C30B 25/12; C23C 16/455; C23C 16/458

(52) U.S. Cl. CPC C30B 25/12; C23C 16/4584; C23C 16/45504

(57) ABSTRACT

Embodiments of the present disclosure provide an improved susceptor for a substrate processing chamber. In one embodiment, the susceptor comprises an outer peripheral edge circumscribing a pocket, wherein the pocket has a concave surface that is recessed from the outer peripheral edge, and an angled support surface disposed between the outer peripheral edge and the pocket, wherein the angled support surface is inclined with respect to a horizontal surface of the outer peripheral edge.

### CROSS-REFERENCE TO RELATED APPLICATIONS

This application claims benefit of U.S. provisional patent application Ser. No. 62/046,451, filed Sep. 5, 2014, which is herein incorporated by reference.

### FIELD

Embodiments of the disclosure generally relate to a susceptor for use in a thermal deposition chamber, such as an epitaxial deposition chamber utilized in semiconductor fabrication processes.

### BACKGROUND

Modern processes for manufacturing semiconductor devices require precise adjustment of many process parameters to achieve high levels of device performance, product yield, and overall product quality. For processes that include the formation of semiconductive layers on substrates with epitaxial (“EPI”) film growth, numerous process parameters have to be carefully controlled, including the substrate temperature, the pressures and flow rates precursor materials, the formation time, and the distribution of power among the heating elements surrounding the substrate, among other process parameters.

There is an ongoing need for increasing yield of devices, as well as the number of devices, per substrate. Utilization of substrates with a larger surface area for device formation increases the number of devices per substrate. However, increasing the surface area of the substrate creates numerous process parameter issues. For example, mere scaling-up of chamber components to accommodate larger substrate sizes has been found to not be sufficient to achieve desirable results.

Thus, there is a need for an improved EPI process chamber and components that provides for uniform deposition of semiconductive layers on a substrate having a larger usable surface area.

### SUMMARY

In one embodiment, a susceptor for use in a process chamber is provided. The susceptor comprises an outer peripheral edge circumscribing a pocket, wherein the pocket has a concave surface that is recessed from the outer peripheral edge, and an angled support surface disposed between the outer peripheral edge and the pocket, wherein the angled support surface is inclined with respect to a horizontal surface of the outer peripheral edge.

In another embodiment, a pre-heat ring for use in a process chamber is provided. The pre-heat ring comprises a circular body comprising an outer peripheral edge circumscribing an opening, wherein the outer peripheral edge comprises a top surface and a bottom surface parallel to the top surface, and a recess formed in the bottom surface of the outer peripheral edge, wherein the top surface extends a first radial width inwardly from an edge of the circular body to the opening, the bottom surface extends a second radial width inwardly from the edge of the circular body to the recess, and the first radial width is greater than the second radial width, wherein the circular body comprises a first thickness and a second thickness, and the second thickness is about 75% to about 86% of the first thickness.

In yet another embodiment, a process chamber for processing a substrate is provided. The process chamber comprises a rotatable susceptor disposed within the process chamber, the susceptor comprises a first outer peripheral edge circumscribing a pocket, wherein the pocket has a concave surface that is recessed from the first outer peripheral edge, and an angled support surface disposed between the first outer peripheral edge and the pocket, wherein the angled support surface is inclined with respect to a horizontal surface of the first outer peripheral edge, and a lower dome disposed relatively below the susceptor, an upper dome disposed relatively above the susceptor, the upper dome being opposed to the lower dome, and the upper dome and the lower dome generally defining an internal volume of the process chamber, and a pre-heat ring disposed within an inner circumference of the process chamber and around a periphery of the susceptor.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic isometric view of a susceptor according to one embodiment of the present disclosure.

FIG. 2 is a cross-sectional view of the susceptor of FIG. 1.

FIG. 3 is an enlarged cross-sectional view of the susceptor of FIG. 2.

FIG. 4 is a schematic isometric view of a pre-heat ring according to one embodiment of the present disclosure.

FIG. 5 is a cross-sectional view of the pre-heat ring of FIG. 4.

FIG. 6 is an enlarged cross-sectional view of the pre-heat ring of FIG. 5.

FIG. 7 is a schematic cross-sectional view of a process chamber that may be used to practice embodiments of the present disclosure.

### DETAILED DESCRIPTION

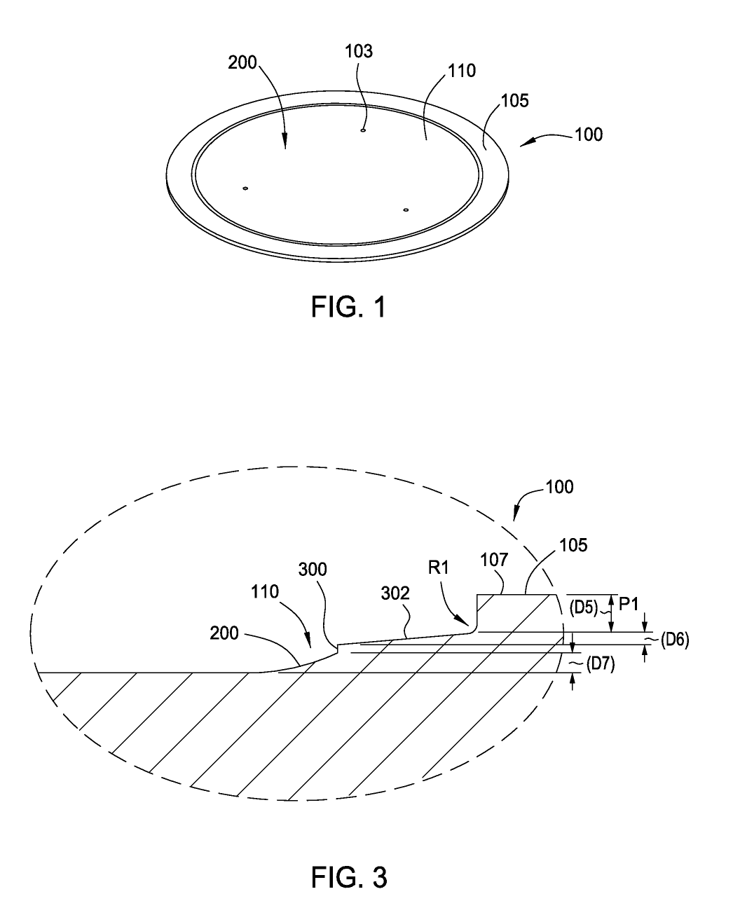

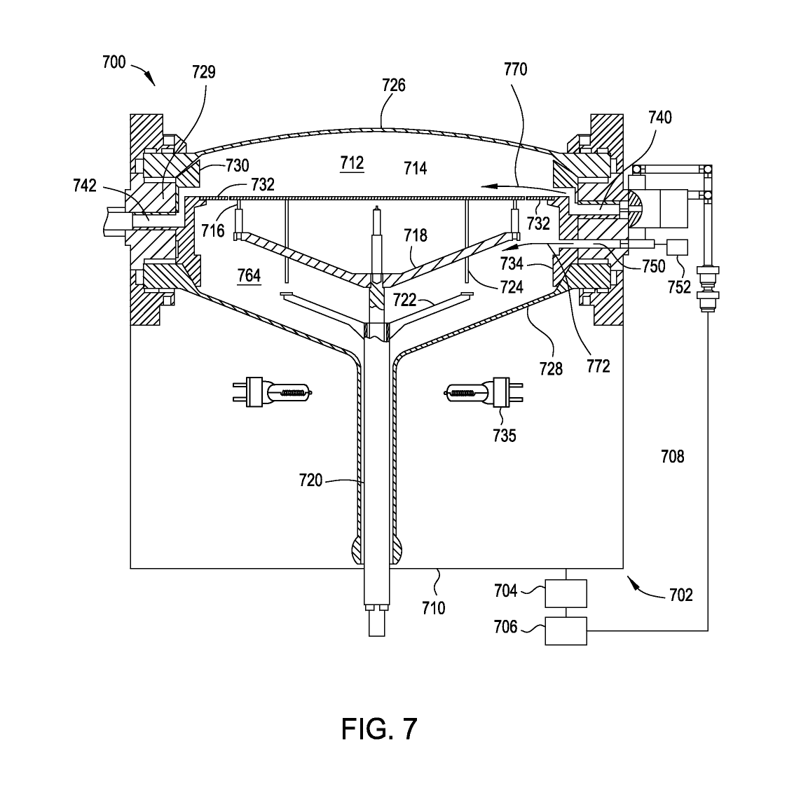

FIG. 1 is a schematic isometric view of a susceptor 100 according to embodiments described herein. The susceptor 100 includes an outer peripheral edge 105 circumscribing a recessed pocket 110 where a substrate (not shown) may be supported. The susceptor 100 may be positioned in a semiconductor process chamber, such as a chemical vapor deposition chamber or an epitaxial deposition chamber. One exemplary process chamber that may be used to practice embodiments of the present disclosure is illustrated in FIG. 7. The recessed pocket 110 is sized to receive the majority of the substrate. The recessed pocket 110 may include a surface 200 that is recessed from the outer peripheral edge 105. The pocket 110 thus prevents the substrate from slipping out during processing. The susceptor 100 may be an annular plate made of a ceramic material or a graphite material, such as graphite that may be coated with silicon carbide. Lift pin holes 103 are shown in the pocket 110.

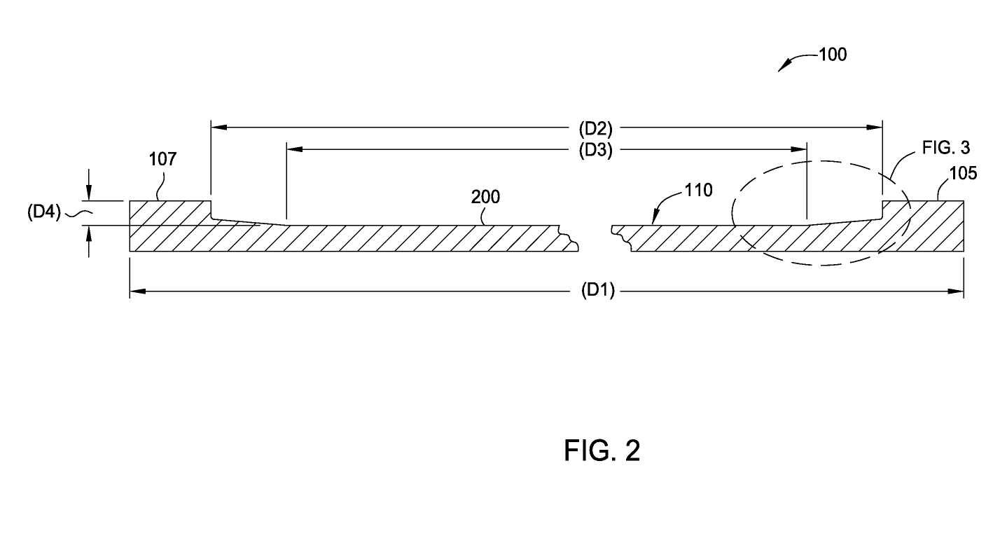

FIG. 2 is a side cross-sectional view of the susceptor 100 of FIG. 1. The susceptor 100 includes a first dimension D1 measuring from an outer diameter of the susceptor 100. The outer diameter of the susceptor 100 is less than an inner circumference of the semiconductor process chamber, such as the process chamber of FIG. 7. The first dimension D1 is greater than a second dimension D2 of the pocket 110, which is measured from an inner diameter of the outer peripheral edge 105. The susceptor 100 may include a ledge 300 (see FIG. 3) disposed between an outer diameter of the surface 200 and the inner diameter of the outer peripheral edge 105. The pocket 110 also includes a third dimension D3 measuring from an inner diameter of the ledge 300. The third dimension D3 is less than the second dimension D2. Each of the dimensions D1, D2 and D3 may be diameters of the susceptor 100. In one embodiment, the third dimension D3 is about 90% to about 97% of the second dimension D2. The second dimension D2 is about 75% to about 90% of the first diameter D1. For a 450 mm substrate, the first dimension D1 may be about 500 mm to about 560 mm, such as about 520 mm to about 540 mm, for example about 535 mm. The pocket 110 (i.e., the dimension D2 and/or the dimension D3) may be sized to receive a 450 mm substrate, in one embodiment.

A depth D4 of the surface 200 may be about 1 mm to about 2 mm from a top surface 107 of the outer peripheral edge 105. In some embodiments, the surface 200 is slightly concave to prevent portions of an underside of a sagging substrate from contacting the susceptor during processing. The surface 200 may include a pocket surface radius (spherical radius) of about 34,000 mm to about 35,000 mm, such as about 34,200 mm to about 34,300 mm. The pocket surface radius may be utilized to prevent contact between a substrate surface and at least a portion of the surface 200 during processing, even when the substrate is bowed. The height and/or the pocket surface radius of the recessed pocket 110 are variable based on the thickness of the substrate supported by the susceptor 100.

FIG. 3 is an enlarged cross-sectional view showing a portion of the susceptor of FIG. 2. The outer peripheral edge 105 protrudes from an upper surface of the susceptor. In some embodiments, an angled support surface 302, which serves as part of a supporting surface for a substrate, is disposed between the pocket 110 and the outer peripheral edge 105. Particularly, the angled support surface 302 is between the inner diameter of the outer peripheral edge 105 (i.e., dimension D2) and the inner diameter of the ledge 300 (i.e., dimension D3). The angled support surface 302 can reduce a contacting surface area between a substrate and the susceptor 100 when an edge of the substrate is supported by the angled support surface 302. In one embodiment, the top surface 107 of the outer peripheral edge 105 is higher than the angled support surface 302 by a dimension D5, which may be less than about 3 mm, such as about 0.6 mm to about 1.2 mm, for example about 0.8 mm.

In one embodiment, a fillet radius “R1” is formed at an interface where the outer peripheral edge 105 and the angled support surface 302 meet. The fillet radius R1 may be a continuously curved concave. In various embodiments, the fillet radius “R1” ranges between about 0.1 inches and about 0.5 inches, such as about 0.15 inches and about 0.2 inches.

The angled support surface 302 may be inclined with respect to a horizontal surface, for example the top surface 107 of the outer peripheral edge 105. The angled support surface 302 may be angled between about 1 degree to about 10 degrees, such as about 2 degrees to about 6 degrees. Varying the slope or dimensions of the angled support surface 302 can control the size of a gap between the bottom of the substrate and the surface 200 of the pocket 110, or the height of the bottom of the substrate relative to the pocket 110. In the embodiment shown in FIG. 3, the cross-sectional view shows the angled support surface 302 extending radially inward from the fillet radius R1 toward the surface 200 by a height shown as a dimension D6, which may be less than about 1 mm. The angled support surface 302 ends at the outer diameter of the surface 200. The surface 200 may be recessed from the bottom of the ledge 300 by a height shown as a dimension D7. Dimension D7 may be greater than the dimension D6. In one embodiment, the dimension D6 is about 65% to about 85% of the dimension D7, for example about 77% of the dimension D7. In other embodiments, the dimension D7 is about a 30% increase from the dimension D6. In one example, dimension D6 is about 0.05 mm to about 0.15 mm, for example about 0.1 mm. In some embodiments, the top surface 107 may be roughened to about 5 Ra to about 7 Ra.

The susceptor 100 with features described herein (e.g., angled support surface and pocket surface radius) has been tested and results show good heat transfer between a substrate and the surface 200 without contact between the substrate and the surface 200. Utilization of the ledge 300 provides heat transfer by a minimum contact between the substrate and the angled support surface 302.

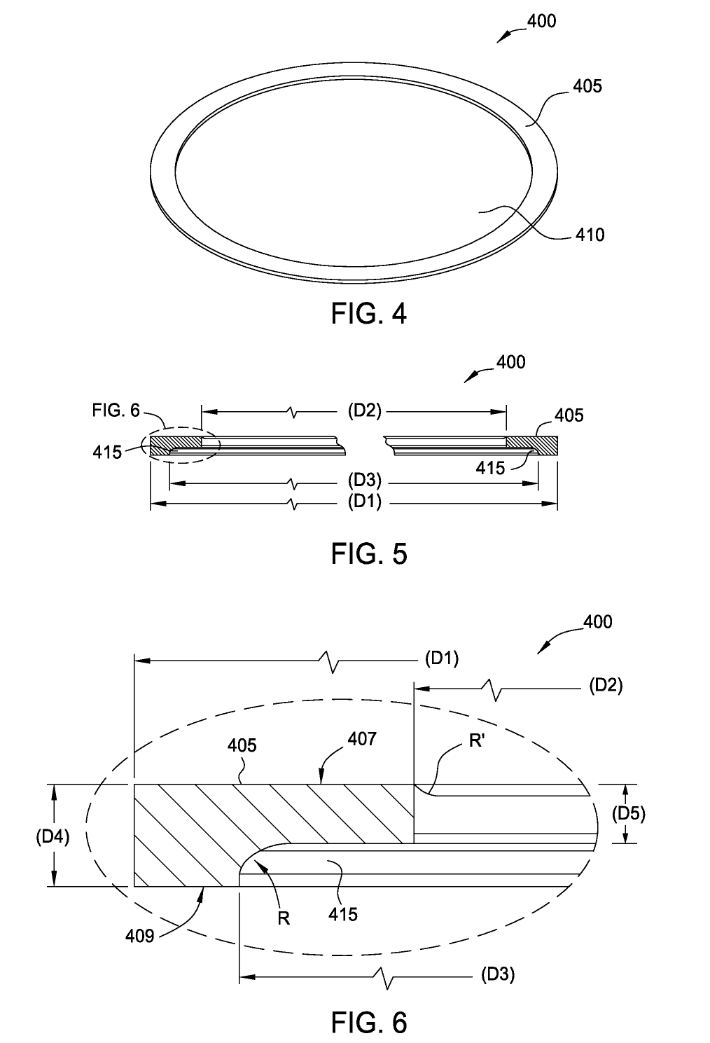

FIG. 4 is a schematic isometric view of a pre-heat ring 400 according to embodiments described herein. The pre-heat ring 400 may be positioned in a semiconductor process chamber, such as such as a chemical vapor deposition chamber or an epitaxial deposition chamber. Particularly, the pre-heat ring 400 is configured to be disposed around the periphery of the susceptor (e.g., the susceptor 100 of FIGS. 1-3) while the susceptor is in a processing position. One exemplary process chamber that may be used to practice embodiments of the present disclosure is illustrated in FIG. 7. The pre-heat ring 400 includes an outer peripheral edge 405 circumscribing an opening 410 where a susceptor, such as the susceptor 100 of FIGS. 1-3, may be positioned. The pre-heat ring 400 includes a circular body made of a ceramic material or a carbon material, such as graphite that may be coated with silicon carbide.

FIG. 5 is a side cross-sectional view of the pre-heat ring 400 of FIG. 4. The pre-heat ring 400 includes a first dimension D1 measuring from an outer diameter of the outer peripheral edge 405, and a second dimension D2 measuring from an inner diameter of the outer peripheral edge 405. The outer diameter of the outer peripheral edge has a circumference less than a circumference of the semiconductor process chamber, such as the process chamber of FIG. 7. The second dimension D2 may be substantially equal to a diameter of the opening 410. The first dimension D1 is less than an inner circumference of the semiconductor process chamber, such as the process chamber of FIG. 7. The pre-heat ring 400 also includes a recess 415 formed in a bottom surface (e.g., bottom surface 409) of the outer peripheral edge 405. The recess 415 includes a third dimension D3 measuring from an outer diameter of the recess 145. The third dimension D3 is less than the first dimension D1 but greater than the second dimension D2. Each of the dimensions D1, D2 and D3 may be diameters of the pre-heat ring 400. The recess 415 may be utilized to contact a susceptor (not shown) in use, and the third dimension D3 may be substantially equal to or slightly larger than an outer diameter of the susceptor (e.g., the dimension D1 of FIG. 2).

In one embodiment, the dimension D3 is about 90% to about 98% of the first dimension D1, for example about 94% to about 96% of the first dimension D1, and the second dimension D2 is about 80% to about 90% of the first dimension D1, for example about 84% to about 87% of the first dimension D1. For a 450 mm substrate, the first dimension D1 may be about 605 mm to about 630 mm, such as about 615 mm to about 625 mm, for example 620 mm. The pre-heat ring 400 may be sized to be utilized in the processing of a 450 mm substrate, in one embodiment.

FIG. 6 is an enlarged cross-sectional view of the pre-heat ring 400 of FIG. 5. The pre-heat ring 400, which is a circular body, may include a first thickness (i.e., outer thickness) shown as dimension D4 and a second thickness (i.e., inner thickness) shown as dimension D5. Dimension D4 is greater than the dimension D5. In one embodiment, the dimension D5 is about 75% to about 86% of the dimension D4, for example about 81% of the dimension D4. The outer peripheral edge 405 of the pre-heat ring 400 includes a top surface 407 and a bottom surface 409 that are substantially parallel (i.e., parallelism of less than about 1.0 mm). The top surface 407 extends a first radial width inwardly from an edge of the pre-heat ring 400 to the opening 410, while the bottom surface 409 extends a second radial width inwardly from the edge of the pre-heat ring 400 to the recess 415. The first radial width is greater than the second radial width. In one embodiment, the first radial width is about 5 mm to about 20 mm, such as about 8 mm to about 16 mm, for example about 10 mm. At least the bottom surface 409 includes a flatness of less than about 1.0 mm, in some embodiments. A fillet radius “R” is formed at a corner of the recess 415. A chamfer “R′” may also be formed on corners of the pre-heat ring 400, e.g., an interface where an outer edge of the opening 410 and an inner edge of the outer peripheral edge 405 meet. One or both of R and R′ may be about less than 0.5 mm in one embodiment. In one embodiment, the dimension D5 is about 6.00 mm.

The radial width of the outer peripheral edge 405 is utilized to absorb heat from energy sources, such as lamps 735 shown in FIG. 7. Precursor gases are typically configured to flow across the outer peripheral edge 405 in a manner substantially parallel to the top surface 407 and the gases are pre-heated prior to reaching a substrate positioned on a susceptor, such as the susceptor 100 of FIGS. 1-3, in the processing chamber. The pre-heat ring 400 has been tested and results show that the flow of the precursor gas can establish a laminar-flow boundary layer over and across the top surface 407 of the pre-heat ring 400. Particularly, the boundary layer, which improves heat transfer from the pre-heat ring to the precursor gas, is fully developed before the precursor gas reaching the substrate. As a result, the precursor gas gains enough heat before entering the process chamber, which in turn increases substrate throughput and deposition uniformity.

FIG. 7 illustrates a schematic sectional view of an exemplary process chamber 700 that may be used to practice embodiments of the present disclosure. The process chamber 700 is configured to process a 300 mm substrate or larger, for example a 450 mm substrate. While the process chamber 700 is described below to be utilized to practice various embodiments described herein, other semiconductor process chamber from a different manufacturer may also be used to practice the embodiment described in this disclosure. The process chamber 700 may be adapted for performing chemical vapor deposition, such as epitaxial deposition processes.

The process chamber 700 illustratively includes a chamber body 702, support systems 704, and a controller 706. The chamber body 702 has an upper dome 726, a side wall 708 and a bottom wall 710 defining an interior processing region 712. A susceptor 714 used for supporting a substrate, such as the susceptor 100 shown in FIGS. 1 to 3, may be disposed in the interior processing region 712. The susceptor 714 is rotated and supported by support posts 716, which are connected with supporting arms 718 that extend from a shaft 720. During operation, the substrate disposed on the susceptor 714 may be raised by substrate lift arms 722 through lift pins 724.

An upper dome 726 is disposed over the susceptor 714 and a lower dome 728 is disposed below the susceptor 714. Deposition processes generally occur on the upper surface of the substrate disposed on the susceptor 714 within the interior processing region 712.

An upper liner 730 is disposed below the upper dome 726 and is adapted to prevent unwanted deposition onto chamber components, such as a base ring 729 or a peripheral flange 731 which engages the central window portion 733 of the upper dome 726 around a circumference of the central window portion 733. The upper liner 730 is positioned adjacent to a pre-heat ring 732. The pre-heat ring 732 is configured to be disposed around the periphery of the susceptor 714 while the susceptor 714 is in a processing position. The radial width of the pre-heat ring 732 extends to a degree between the susceptor 714 and a ring support 734 to prevent or minimize leakage of heat/light noise from the lamps 735 to the device side of the substrate while providing a pre-heat zone for the process gases flowing thereabove. The pre-heat ring 732 is removably disposed on the ring support 734 that supports and positions the pre-heat ring 732 such that the process gas flows into the interior processing region 712 in a laminar flow fashion (e.g., a generally radially inward direction as indicated by flow path 770) across an upper surface of the susceptor 714. The ring support 734 may be a liner disposed within the process chamber.

The base ring 729 may have a ring body sized to fit within an inner circumference of the processing chamber 700. The ring body may have a generally circular shape. The inner circumference of the base ring 729 is configured to receive the ring support 734. In one example, the ring support 734 is sized to be nested within or surrounded by an inner circumference of the base ring 729.

The processing chamber 700 includes a plurality of heat sources, such as lamps 735, which are adapted to provide thermal energy to components positioned within the process chamber 700. For example, the lamps 735 may be adapted to provide thermal energy to the substrate and the pre-heat ring 732, resulting in thermal decomposition of the process gases onto the substrate to form one or more layers on the substrate. In some embodiments, the array of radiant heating lamps 735 may be alternatively or additionally disposed over the upper dome 726. The lower dome 728 may be formed from an optically transparent material, such as quartz, to facilitate the passage of thermal radiation therethrough. The temperature of the pre-heat ring 732 during operation may be about 100 degrees Celsius to about 800 degrees Celsius. During processing, the susceptor 714 may be heated to 1000 degrees Celsius and the pre-heat ring 732 may be heated to about 650-750 degrees Celsius. The heated pre-heat ring 732 activates the process gases as the process gases flow into the process chamber 700 through the process gas inlet 740 that is formed through the base ring 729. The process gases exit the process chamber 700 through the process gas outlet 742 disposed opposite the process gas inlet 740. As the process gas inlet 740, the susceptor 714 and the process gas outlet 742 are at about the same elevation during processing, the process gases are flowed along flow path 770 across the upper surface of the substrate (not shown) in a generally planar, laminar flow fashion to the process gas outlet 742. Further radial uniformity may be provided by the rotation of the substrate through the susceptor 714.

While one process gas inlet 740 is shown, the process gas inlet 740 may include two or more gas inlets for delivering two or more individual gas flows. The process gas inlet 740 may be configured to provide individual gas flows with varied parameters, such as velocity, density, or composition. In one embodiment where multiple process gas inlets are adapted, the process gas inlet 740 may be distributed along a portion of the base ring 729 in a substantial linear arrangement to provide a gas flow that is wide enough to substantially cover the diameter of the substrate. For example, the process gas inlets 740 may be arranged to the extent possible in at least one linear group to provide a gas flow generally corresponding to the diameter of the substrate.

The processing chamber 700 may include a purge gas inlet 750 formed through the base ring 729. The purge gas inlet 750 may be disposed at an elevation below the process gas inlet 740. In one example, the pre-heat ring 732 is disposed between the process gas inlet 740 and the purge gas inlet 750. The purge gas inlet 250 may provide a flow of an inert purge gas, such as hydrogen, from a purge gas source 752 into the lower portion 754 (i.e., a processing region below the susceptor 714) of the processing chamber 700 at a pressure greater than the pressure of the process gases in the upper portion (i.e., a processing region above the susceptor 714) of the processing chamber 700. In one embodiment, the purge gas inlet 750 is configured to direct the purge gas in a generally radially inward direction. During the film deposition process, the susceptor 714 may be located at a position such that the purge gas flows down and round along flow path 772 across back side of the susceptor 714 in a laminar flow fashion. The flowing of the purge gas is believed to prevent or substantially avoid the flow of the process gas from entering into the lower portion 754, or to reduce diffusion of the process gas entering the lower portion 754. The purge gas exits the lower portion 754 and is exhausted out of the processing chamber 700 through the process gas outlet 742, which is located at the side opposite the purge gas inlet 750.

The support system 704 may include components used to execute and monitor pre-determined processes, such as the growth of films in the processing chamber 700. A controller 706 is coupled to the support system 704 and is adapted to control the processing chamber 700 and support system 704.

Advantages of the present disclosure include an improved pre-heat ring which has an outer peripheral edge circumscribing an opening. The outer peripheral edge has a radial width that allows for the flow of the precursor gas to be fully developed into a laminar-flow boundary layer over a top surface of the pre-heat ring before the precursor gas reaching the substrate. The boundary layer improves heat transfer from the pre-heat ring to the precursor gas. As a result, the precursor gas gains enough heat before entering the process chamber, which in turn increases substrate throughput and deposition uniformity. The opening of the pre-heat ring also allows an improved susceptor to be positioned therein. The susceptor has a recessed pocket surrounded by an angled support surface, which reduces a contacting surface area between the substrate and the susceptor. The recessed pocket has a surface that is slightly concave to prevent contact between the substrate and the recessed pocket, even when the substrate is bowed.

While the foregoing is directed to embodiments of the present disclosure, other and further embodiments of the disclosure may be devised without departing from the basic scope thereof.

1. A susceptor for a substrate processing chamber, comprising:
an outer peripheral edge circumscribing a pocket, wherein the pocket has a concave surface that is recessed from the outer peripheral edge;
an angled support surface disposed between the outer peripheral edge and the pocket, wherein the angled support surface is inclined with respect to a horizontal surface of the outer peripheral edge by about 1 degree to about 10 degrees; and
a ledge disposed between an outer diameter of the concave surface and an inner diameter of the outer peripheral edge, wherein an inner diameter of the ledge is about 90% to about 97% of an inner diameter of the outer peripheral edge.

2. The susceptor of claim 1, wherein the concave surface has a surface radius of about 34,000 mm to about 35,000 mm.

3-4. (canceled)

5. The susceptor of claim 1, wherein the inner diameter of the outer peripheral edge is about 75% to about 90% of an outer diameter of the outer peripheral edge.

6. The susceptor of claim 1, wherein a top surface of the outer peripheral edge is higher than the angled support surface by a dimension of less than about 3 mm.

7. The susceptor of claim 1, further comprising a fillet radius formed at an interface between the outer peripheral edge and the angled support surface.

8. (canceled)

9. The susceptor of claim 7, wherein the angled support surface extends radially inward from the fillet radius toward the concave surface.

10. The susceptor of claim 9, wherein the angled support surface ends at an outer diameter of the concave surface.

11. A pre-heat ring for a substrate processing chamber, comprising:
a circular body comprising an outer peripheral edge circumscribing an opening, wherein the outer peripheral edge comprises a top surface and a bottom surface parallel to the top surface;
a recess formed in the bottom surface of the outer peripheral edge, wherein the top surface extends a first radial width inwardly from an edge of the circular body to the opening, the bottom surface extends a second radial width inwardly from the edge of the circular body to the recess, and the first radial width is greater than the second radial width, wherein the circular body comprises a first thickness and a second thickness, and the second thickness is about 75% to about 86% of the first thickness; and
a fillet radius formed at a corner of the recess.

12. The pre-heat ring of claim 11, wherein the inner diameter of the outer peripheral edge is about 80% to about 90% of an outer diameter of the outer peripheral edge.

13. The pre-heat ring of claim 12, wherein an outer diameter of the recess is about 90% to about 98% of the outer diameter of the outer peripheral edge.

14.

15. The pre-heat ring of claim 11, wherein the fillet radius is about 0.5 mm.

16. A process chamber for processing a substrate, comprising:
a rotatable susceptor disposed within the process chamber, the susceptor comprises:
a first outer peripheral edge circumscribing a pocket, wherein the pocket has a concave surface that is recessed from the first outer peripheral edge; and
an angled support surface disposed between the first outer peripheral edge and the pocket, wherein the angled support surface is inclined with respect to a horizontal surface of the first outer peripheral edge by about 1 degree to about 10 degrees; and
a lower dome disposed relatively below the susceptor;
an upper dome disposed relatively above the susceptor, the upper dome being opposed to the lower dome, and the upper dome and the lower dome generally defining an internal volume of the process chamber; and
a pre-heat ring disposed within an inner circumference of the process chamber and around a periphery of the susceptor.

17. The process chamber of claim 16, wherein the pre-heat ring comprises:
a circular body comprising a second outer peripheral edge circumscribing an opening, wherein the second outer peripheral edge comprises a top surface and a bottom surface parallel to the top surface;
a recess formed in the bottom surface of the second outer peripheral edge, wherein the top surface extends a first radial width inwardly from an edge of the circular body to the opening, the bottom surface extends a second radial width inwardly from the edge of the circular body to the recess, and the first radial width is greater than the second radial width, wherein the circular body comprises a first thickness and a second thickness, and the second thickness is about 75% to about 86% of the first thickness; and
a fillet radius formed at a corner of the recess.

18. The process chamber of claim 16, wherein an inner diameter of the first outer peripheral edge is about 75% to about 90% of an outer diameter of the first outer peripheral edge.

19. (canceled)

20. The process chamber of claim 17, wherein the inner diameter of the second outer peripheral edge of the pre-heat ring is about 80% to about 90% of an outer diameter of the second outer peripheral edge.

21. The susceptor of claim 1, wherein a top surface of the outer peripheral edge is roughened to about 5 Ra to about 7 Ra.

22. The susceptor of claim 7, wherein the fillet radius is between about 0.1 inches and about 0.5 inches.
